(19) United States
(12) Patent Application Publication
(10) Pub. No.: US 2001/0003671 A1
(43) Pub. Date: Jun. 14, 2001

(54) METHOD FOR MANUFACTURING SEMICONDUCTOR DEVICE HAVING REFRACTORY METAL SILICIDE FILM

(76) Inventor: SHIZUO OGURO, TOKYO (JP)

Correspondence Address: HUTCHINS, WHEELER & DITTMAR, 101 FEDERAL STREET, BOSTON, MA, 02110, US

(21) Appl. No.: 09/172,800

(22) Filed: Oct. 14, 1998

(30) Foreign Application Priority Data
Oct. 15, 1997 (JP) 09-281673

(51) Int. Cl. H01L 21/44; H01L 21/4763

(52) U.S. Cl. 438/683; 438/682; 438/649

(57) ABSTRACT

First, there is formed a silicon film doped with impurities on a semiconductor substrate. Next, a refractory metal film is formed on the silicon film. Then, the silicon film and the refractory metal film are reacted by heat treatment to form a refractory metal silicide film.

### BACKGROUND OF THE INVENTION

1. Field of the Invention

The present invention relates to a method for manufacturing a semiconductor device having a refractory metal silicide film such as a TiSi₂ film which has high heat resistance and less residual defect.

2. Description of the Related Art

Heretofore, it has been the practice to form selectively a refractory metal silicide film such as a TiSi₂ film on a surface of a silicon substrate in a step of manufacturing a semiconductor device having MOS transistor or the like, so as to expect low resistance of element wiring. However, at the time of growth of a refractory metal silicide film, silicon at the surface of the silicon substrate is consumed in the reaction with titanium. Therefore, when a shallow junction is formed in a region in which a refractory metal silicide film is expected to be formed, there is an apprehension for junction destruction to be caused due to the reach of the refractory metal silicide film to the junction. Accordingly, in the semiconductor device which is required to form shallow junction so as to suppress a short channel effect in a MOS transistor (loss in threshold value by the shortening of a channel length), prevention of junction destruction by such refractory metal silicide is necessary.

Accordingly, there is proposed a method for preventing the juncture destruction formed in a silicon substrate by selectively forming a silicon film on the surface of the silicon substrate and forming a refractory metal silicide film by using this silicon film (Japanese Patent Application Laid-Open (JP-A) No. Hei 6-61180). FIGS. 1A to 1C are the sectional views showing the conventional electrode forming method described in Japanese Patent Application Laid-Open (JP-A) No. Hei 6-61180 in order of process.

In the conventional electrode forming method described in this publication, first, as shown in FIG. 1A, there are formed an element separation oxide film 62, a P-well region 63 and an N⁺source-drain region 64 at the surface of a P-type silicon substrate 61, and a gate insulation film 65, a gate electrode 66 and an oxide film spacer 67 on the P-type silicon substrate 61.

Subsequently, as shown in FIG. 1B, a non-doped silicon film 68 having no induction of impurities is selectively formed on each surface of the region to be silicidized, or in this case on the surfaces of the source-drain region 64 and the gate electrode 66, respectively. Next, a titanium film 69 is formed as a metal film to be silicidized in the region which includes the silicon film 68.

Thereafter, as shown in FIG. 1C, by providing the titanium film 69 and the silicon film 68 with heat treatment, the titanium film 69 and the silicon film 68 are mutually reacted. By this step, a TiSi₂ film 68a is formed on each surface of the source-drain region 64 and the gate electrode 66. Next, the non-reacted titanium film 69 is removed by selective etching.

According to this conventional method, because the TiSi₂ film 68a is formed in the region in which the silicon film 68 exists, it does not occur for silicon in the silicon substrate 61 or the like on the lower layer thereof, especially, silicon in the source-drain region 64, to be consumed. Accordingly, destruction of PN junction in the source-drain region 64 is prevented.

Recently, in various semiconductor devices, developments of size reduction and speed increase of chips have been in progress. However, when a chip size becomes fine, in case of existence of chips having different functions such as a memory device, a logic device, etc. individually, even if the individual devices can act at high speed, depending on the parasitic resistance or parasitic capacity of them at connecting parts, speed elevation of the system as a whole is apt to be suppressed.

When devices having heterogeneous functions are assembled in a single chip, the loss in speed elevation at the connecting parts as described above can be suppressed. Furthermore, with respect to the chip size, increase in size by packaging is no longer observed, and effective miniaturization is possible.

However, in manufacturing a semiconductor device in which the memory devices and the logic devices are integrated, due to the cause of the TiSi₂ film to be formed in the semiconductor device, the manufacturing processes for the respective devices cannot be readily unified. Thus, in the logic devices, it is necessary to form a TiSi₂ film or the like on a source-drain region and a gate electrode to lower the resistance of the source-drain region and the gate electrode for speed elevation purpose. On the other hand, in a DRAM which has high integration degree, it is necessary to form a capacitance portion for memorizing information on the inter-layer insulation film after formation of the MOS transistor. And, for forming the capacitance portion, high temperature heat treatment for forming capacitance insulation film or the like is necessary. Accordingly, in case of forming a TiSi₂ film in such a semiconductor device by the technique disclosed in the foregoing publication, the TiSi₂ film in a previously formed logic device region shows aggregation by high temperature heat treatment and presents a broken state. Therefore, there arises a problem on heat resistance.

In order to avoid such aggregation, it is necessary to form a TiSi₂ film after forming a capacitance portion in a memory device region. However, for such purpose, it is necessary to remove a once formed inter-layer insulation film on a MOS transistor to form the TiSi₂ film in the logic device region, thereby causing remarkable increase in the number of steps.

Accordingly, in order to prevent such increase of the number of steps, it is necessary to form a TiSi₂ film having excellent heat resistance that does not cause aggregation in the subsequent heat treatment process such as a process for forming a capacitance insulation film.

Also, in Japanese Patent Application Laid-Open (JP-B) No. Sho 63-204743, there are proposed the following three semiconductor device manufacturing processes: the first one is to form a silicide layer on a silicon film and provide the silicide layer with nitrogen ion-implantation; the second one is to form a silicide layer on a silicon film by sputtering in an argon gas atmosphere containing nitrogen gas; and the third one is to form a silicide layer on a silicon film in an atmosphere containing nitrogen gas by a CVD process.

However, even by these processes, it is not possible to obtain a TiSi₂ film having sufficient heat resistance.

### SUMMARY OF THE INVENTION

An object of the present invention is to provide a method for manufacturing a semiconductor device having a refractory metal silicide film with excellent heat resistance.

The method for manufacturing a semiconductor device having a refractory metal silicide film according to the present invention comprises the steps of: forming a silicon film doped with impurities on a semiconductor substrate; forming a refractory metal film on said silicon film; and reacting said silicon film and said refractory metal film by heat treatment to form a refractory metal silicide film.

According to the present invention, even in case of a subsequent heat treatment at a high temperature, aggregation in the refractory metal silicide film is suppressed. Accordingly, the resistance of the refractory metal silicide film is maintained in a low condition. In other words, the heat resistance of the refractory metal silicide film is improved.

Further, in case the silicon film is provided with ion-implantation to transform an amorphous state, there is formed a uniform refractory metal silicide film. Therefore, the effects as described above are obtained while preventing the generation of the residual defects and suppressing the increase of the junction leak current.

### BRIEF DESCRIPTION OF THE DRAWINGS

FIGS. 1A to 1C are sectional views showing a conventional method for forming an electrode disclosed in Japanese Patent Application Laid-Open (JP-A) No. Hei 6-61180 in order of process.

FIGS. 2A to 2D are sectional views showing a method for manufacturing a semiconductor device according to the first embodiment of the present invention.

FIG. 3 is a schematic diagram showing an element for measuring a sheet resistance manufactured according to the method of the first embodiment.

FIG. 4 is a sectional view showing a method for manufacturing a semiconductor device according to a comparative example.

FIG. 5 is a graph showing relations between width W of elements taken on the abscissa and sheet resistance of the elements taken on the ordinate.

FIGS. 6A to 6C are sectional views showing a method for manufacturing a semiconductor device according to the second embodiment of the present invention.

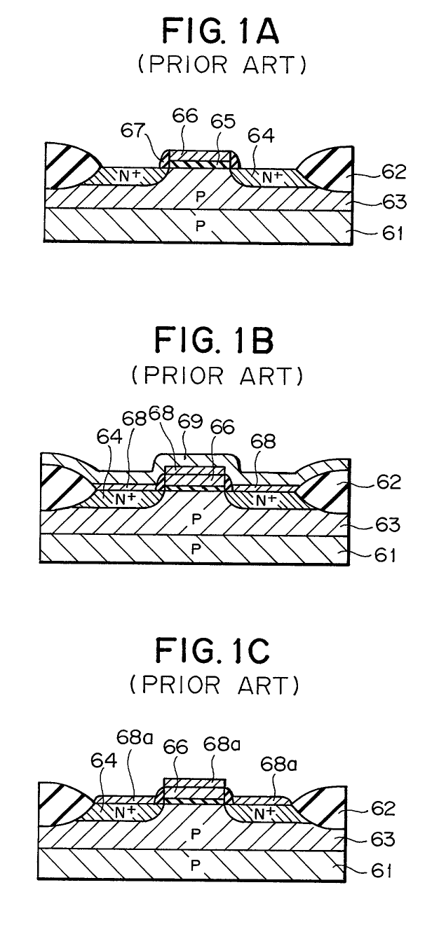

### DETAILED DESCRIPTION OF THE PREFERRED EMBODIMENTS

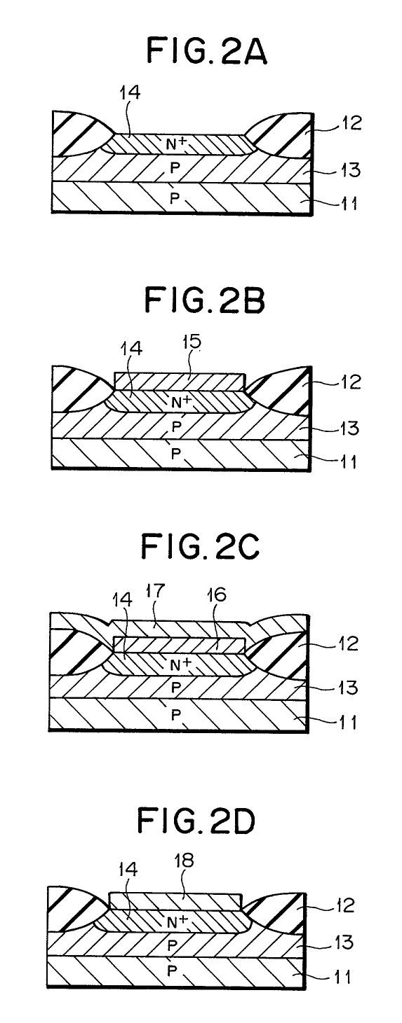

Hereinafter, methods for manufacturing a semiconductor device according to the embodiments of the present invention are materially illustrated with reference to the appended drawings. In the first embodiment, a TiSi₂ film is used for a sheet resistance-measuring element. FIGS. 2A to 2D are the sectional views which show the method for manufacturing a semiconductor device according to the first embodiment of the present invention.

First, as shown in FIG. 2A, an element separation oxide film 12 is selectively formed at the surface of a P-type silicon substrate 11. Next, a P-well region 13 is formed at the surface of the P-type silicon substrate 11 by performing ion-implantation of boron. Further, an N⁺well region 14 is formed at the surface of the P-well region 13 by carrying out ion-implantation of arsenic.

Next, as shown in FIG. 2B, a silicon film 15 having a film thickness of for example 40 nm, dope with boron to a concentration of for example 1×10²¹ cm⁻³ is selectively formed on the N⁺well region 14. As a film forming method at this time, there is used a selective epitaxial growth method or a selective CVD method. Accordingly, the silicon film 15 to be formed is a single crystalline silicon film or a polycrystalline silicon film.

Next, ion-implantation of arsenic is made into a silicon film 15 in the energy of for example 40 keV, and a dosage of 3×10 cm⁻². By this step, the silicon film 15 is transformed into amorphous state, and, as shown in FIG. 2C, an amorphous silicon film 16 is formed. Thereafter, a titanium film 17 having a thickness of for example 30 nm is formed on the amorphous silicon film 16 by sputtering.

Next, the amorphous silicon film 16 is subjected to heat treatment, for example, at 690° C. for 130 seconds by rapid thermal annealing (RTA). By this step, the whole amorphous silicon film 16 is silicidized, and, as shown in FIG. 2D, a TiSi₂ film 18 is formed. Subsequently, the non-reacted titanium film 17 is removed by selective etching. Further, the TiSi₂ film 18 is provided with RTA, for example, at 870° C. for 10 seconds. By this step, a phase transition to a phase having low resistance is caused on the TiSi₂ film 18.

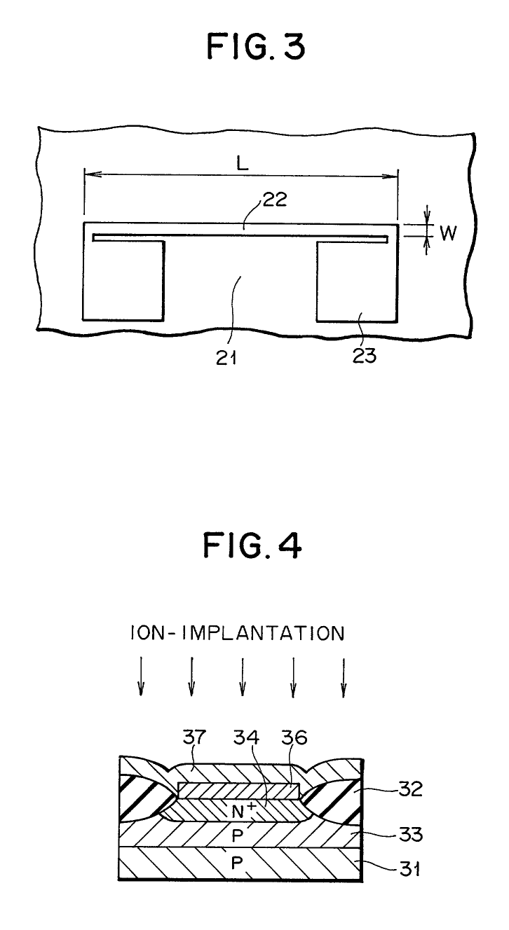

As described above, this embodiment shows the use for a sheet resistance-measuring element. FIG. 3 is a schematic diagram showing a sheet resistance-measuring element manufactured according to the method relating to the first embodiment. For this sheet resistance-measuring element, there is formed a linear TiSi₂ resistor 22 constituted by the TiSi₂ film 18. Its length is L μm, and its width is W μm. Further, on both end portions of it there are formed electrodes 23 having a wide area so as to allow direct measurement of resistance. Furthermore, surrounding the TiSi₂ resistor 22 and the electrode 23, an oxide film 21 is formed.

Also, the silicon film to be formed on the N⁺well region 14 may be a silicon film in which nitrogen is doped to a concentration of, for example, 2×10²¹ cm⁻³.

In case boron is doped, its concentration is desirably 1×10²⁰ to 2×10²¹ cm⁻³.

Here, description is made on the effects obtained by the first embodiment and on the effects obtained by the embodiment of carrying out doping of nitrogen.

First, according to the first embodiment, a sheet resistance-measuring element shown in FIG. 3 was made by adopting a fixed length L of 100 μm, and varying the width W in the range of 0.2 to 2 μm. Next, for evaluating the heat resistance, there were made a sample provided with a heat treatment at 800° C. for 60 minutes and a sample not provided with heat treatment.

Furthermore, according to the embodiment for carrying out doping of nitrogen, a sample as shown in FIG. 3 was made. Further, as a comparative example, there was made a sample as shown in FIG. 3 by a method not provided with doping of impurities. Moreover, by the method of making an amorphous silicon film not provided with doping of impurities, forming a titanium film on the silicon film, conducting ion-implantation of boron, and silicidizing the silicon film, there was made a sample as shown in FIG. 3 as another comparative example. FIG. 4 is a sectional view of the semiconductor device showing the manufacturing method according to the above comparative example.

First, at the surface of a silicon substrate 31 there is formed a junction region consisting of a P-well region 33 and an N-well region 34, which are divided by an element separation oxide film 32. Next, there is formed an amorphous silicon film 36 which is not doped on the junction region. Next, a titanium film 37 is formed by sputtering on the silicon film 36. Subsequently, ion-implantation of boron is carried out in a dosage of 4×10¹⁵ cm⁻². And, the silicon film 36 is silicidized by heat treatment.

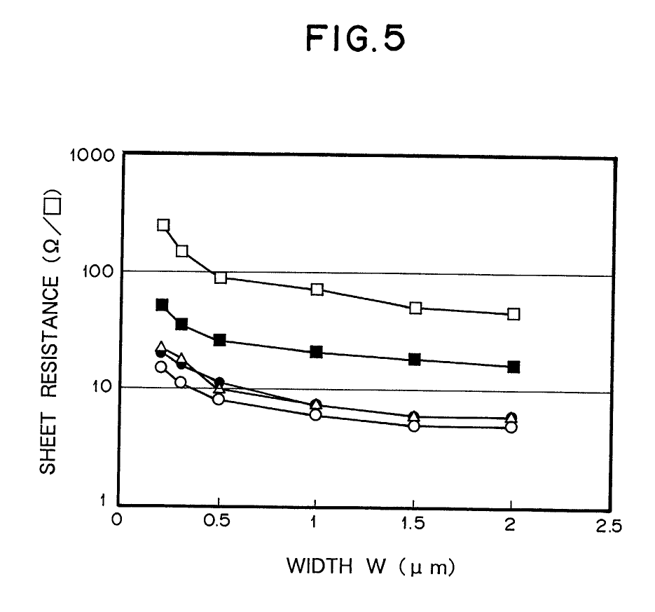

The sheet resistances of these samples were measured. With respect to the samples other than those made by the first embodiment, heat treatment was conducted at 800° C. for 60 minutes for the purpose of evaluating the heat resistance. The results are shown in FIG. 5. FIG. 5 is a graph in which the width W of the elements is taken on the abscissa and the sheet resistance of the elements is taken on the ordinate to show the relations between the two. In FIG. 5, the mark O shows the result of the sample made by the first embodiment after which no heat treatment is given, and the mark ● shows the result of the sample made by the first embodiment after which heat treatment is given. The mark Δ shows the result of the sample provided with nitrogen doping, the mark □ shows the result of the sample not provided with doping of impurities, and the mark ▪ shows the result of the sample implanted of boron into a non-doped silicon film with impurities.

As shown in FIG. 5, according to the embodiments (●, Δ) of the present invention, even if a heat treatment was provided at 800° C. for 60 minutes, the sheet resistance scarcely increased. On the contrary, the sheet resistance of the comparative example (□) not provided with doping of impurities was high by about 1 digit. In the comparative example in which ion-implantation of boron was made after the titanium sputtering (▪), the sheet resistance was high by about half digit.

As reviewed above, according to the embodiment of the present invention using a silicon film doped with boron or nitrogen, even if heat treatment is made at high temperature and for long duration in the subsequent process, a TiSi₂ film having low resistance can be formed without causing aggregation. Namely, a TiSi₂ film having high heat resistance is obtainable.

Moreover, in the first embodiment, there is practiced as an example the ion-implantation of arsenic having the energy of 40 keV and the dose of 3×10¹⁴ cm⁻² for transforming the silicon film 15 into amorphous state, the element to be implanted, energy, and dose conditions are not specifically limited insofar as the conditions are such that the whole doped silicon film is transformed into amorphous state, under which the same effect as that of the first embodiment is obtainable. The element to be implanted may be, for example, silicon, germanium (Ge), etc., and both of them or a combination of them with arsenic may be implanted.

Alternatively, if the film thickness of the titanium film, film thickness of the silicon film doped with impurities, and the RTA conditions for silicidization are all set for silicidizing the silicon film, no ion-implantation may be made for transforming the silicon film into amorphous state. In this case alike, there can be obtained the same effect as that of the first embodiment, too. However, the thickness of the silicon film is desirably 1 to 1.5 times that of the titanium film.

Next, explanation is made on the junction leak current of a semiconductor device manufactured by a process similar to that of the first embodiment. Here, the pattern of a TiSi₂ film is a square having a side of 500 μm.

An inverse bias voltage of 5 V was applied to the region of PN junction of the semiconductor device and the junction leak current at that time was measured. With respect to the samples prepared at the time of the measurement of the sheet resistance, the junction leak current was measured in the similar manner. The results are shown in Table 1 below.

TABLE 1

| Sample | Junction leak current (nA/cm²) |
|---|---|
| ◯ | 0.8 |
| ● | 0.9 |
| Δ | 1.0 |
| ▪ | 5.2 |

As shown in Table 1, according to the embodiments of the present invention (●, Δ), even if a high temperature heat treatment was provided for a long duration of time, there is scarce increase in the junction leak current of the TiSi₂ film.

To the contrary, in the silicon film in which boron was implanted afterwards, the junction leak current showed increase. From this phenomenon, it can be presumed that, in the method of introducing boron into the titanium film or the silicon film by ion-implantation, thrusting through of boron and defects were induced at the time of the ion-implantation in high dose of boron, resulting in increased junction leak current.

In the present invention, because ion-implantation is not used as the means for introducing impurities into the silicon film, no increase in the junction leak current occurs. Although ion-implantation is used for forming the silicon film into amorphous state, due to relatively low dose level of it, no defect is induced by it.

Thus, according to this embodiment of the invention which is designed to use a silicon film doped with boron or nitrogen, thrusting through of impurities and defects are not induced by the high dose ion-implantation. Accordingly, there is obtained a low resistance TiSi₂ film having low resistance in which no junction leak current increases even under a high temperature heat treatment for a long duration.

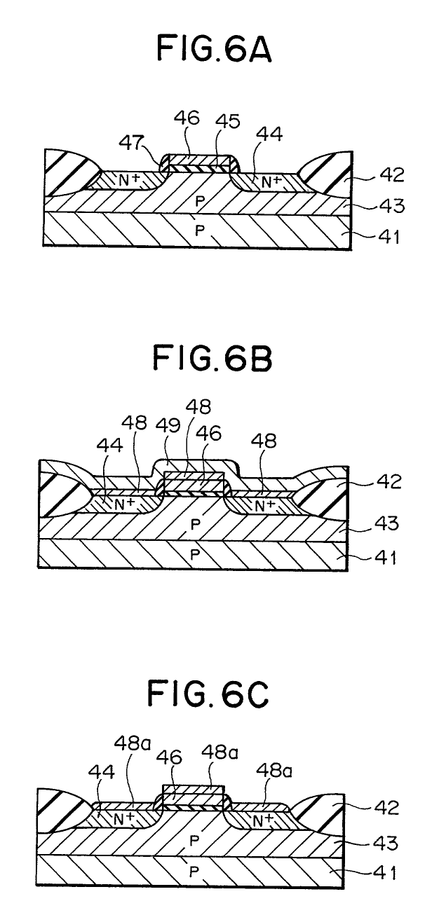

Next, a manufacturing method for a semiconductor device according to the second embodiment of the present invention is described. FIGS. 6A to 6C are the sectional views showing the manufacturing method for a semiconductor device according to the second embodiment of the present invention in order of steps.

First, as shown in FIG. 6A, at the surface of a P-type silicon substrate 41, a P-well region 43 is formed. Next, an element separation oxide film 42, a gate insulation film 45, gate electrode 46 and an oxide film spacer 47 are selectively formed in order. And, an N⁺ source-drain region 44 is selectively formed at the surface of the P-well region 43 using the gate electrode 46 and the like as a mask.

Next, as shown in FIG. 6B, a silicon film 48 doped with impurities is formed selectively on the source-drain region 44 and the gate electrode 46 only. Subsequently, by performing ion-implantation in the silicon film 48, the silicon film 48 is transformed into amorphous state. Next, a titanium film 49 is formed on overall surface by sputtering or the like.

Next, as shown in FIG. 6C, a silicon film 48 and the titanium film 49 are mutually reacted by RTA to silicidize the silicon film 48. By this step, a TiSi₂ film 48a doped with impurities is formed. Thereafter, the non-reacted titanium film 49 is removed by selective etching. In addition, the TiSi₂ film 48a is provided with RTA. By this step, a phase transition to a phase having low resistance occurs on the TiSi₂ film 48a.

In the second embodiment, there are obtained the low resistance source-drain region and the gate electrode which show no aggregation even if subsequently a high temperature heat treatment is provided for a long duration of time. Also, because ion-implantation is not used as the means for introducing impurities into the silicon film 48, increase in the junction leak current is prevented.

What is claimed is:

1. A method for manufacturing a semiconductor device having a refractory metal silicide film, comprising the steps of:
forming a silicon film doped with impurities on a semiconductor substrate;
forming a refractory metal film on said silicon film; and
reacting said silicon film and said refractory metal film by heat treatment to form a refractory metal silicide film.

2. The method for manufacturing a semiconductor device according to claim 1, wherein said refractory metal film is a titanium film, and said refractory metal silicide film is a TiSi₂ film.

3. The method for manufacturing a semiconductor device according to claim 1, wherein said impurities are boron.

4. The method for manufacturing a semiconductor device according to claim 3, wherein the concentration of said impurities in said silicon film is 1×10²⁰ to 2×10²¹ cm⁻³.

5. The method for manufacturing a semiconductor device according to claim 1, wherein said impurities are nitrogen.

6. The method for manufacturing a semiconductor device according to claim 5, wherein the concentration of said impurities in said silicon film is 1×10²⁰ to 5×10²¹ cm⁻³.

7. The method for manufacturing a semiconductor device according to claim 2, wherein the film thickness of said silicon film is 1 to 1.5 times the film thickness of said titanium film.

8. The method for manufacturing a semiconductor device according to claim 1, which further comprising the step of transforming said silicon film into amorphous state between said step of forming said silicon film and said step of forming said refractory metal film.

9. The method for manufacturing a semiconductor device according to claim 8, wherein said step of transforming said silicon film into amorphous state has the step of providing ion-implantation for said silicon film.

10. The method for manufacturing a semiconductor device according to claim 9, wherein said step of providing said ion-implantation is a step of implanting at least one ion selected from the group consisting of arsenic, silicon and germanium.
